(19) United States
(12) Patent Application Publication
(10) Pub. No.: US 2018/0088188 A1
(43) Pub. Date: Mar. 29, 2018

(54) THIN-FILM MAGNETIC SENSOR

(71) Applicant: DAIDO STEEL CO., LTD., Nagoya-shi (JP)

(72) Inventors: Shigenobu Koyama, Nagoya-shi (JP); Jun Totsuka, Nagoya-shi (JP); Akira Mitsuda, Nagoya-shi (JP)

(21) Appl. No.: 15/713,184

(22) Filed: Sep. 22, 2017

(30) Foreign Application Priority Data
Sep. 29, 2016 (JP) 2016-190765

(51) Int. Cl. G01R 33/09; G01R 33/05

(52) U.S. Cl. CPC G01R 33/093; G01R 33/05

(57) ABSTRACT

The present invention relates to a thin-film magnetic sensor, and more particularly relates to a thin-film magnetic sensor capable of accurately applying a relatively large bias magnetic field to a high-sensitivity element without causing increase in electric power consumption or increase in element size.

### FIELD OF THE INVENTION

The present invention relates to a thin-film magnetic sensor, and more particularly relates to a thin-film magnetic sensor capable of accurately applying a relatively large bias magnetic field to a high-sensitivity element without causing increase in electric power consumption or increase in element size.

### BACKGROUND OF THE INVENTION

A magnetic sensor is an electronic device for converting a detected amount such as electromagnetic force (for example, current, voltage, electric power, magnetic field or magnetic flux), dynamic quantity (for example, position, speed, acceleration, displacement, distance, tension, pressure, torque, temperature or humidity) or biochemical quantity, into voltage through a magnetic field. Such magnetic sensors are classified into some types of sensors depending on their methods for detecting the magnetic field. The types include a Hall sensor, an anisotropic magnetoresistive sensor (hereinafter also referred to as AMR sensor), a giant magnetoresistive sensor (hereinafter also referred to as GMR sensor), etc.

Among those sensors, GMR sensors are advantageous in that:

(1) GMR sensors have an extremely large maximum value in the rate of change in electrical resistivity (that is to say, MR ratio=Δρ/ρ₀ (Δρ=ρ_{H}−ρ₀, in which pH is electrical resistivity where an external magnetic field is H, and ρ₀ is electrical resistivity where an external magnetic field is 0)) in comparison with AMR sensors;
(2) GMR sensors have a small temperature change in resistance value in comparison with Hall sensors; and
(3) GMR sensors are suitable for miniaturization because materials having a giant magnetoresistive effect (hereinafter also referred to as GMR effect) are used as their materials. Accordingly, GMR sensors have been expected to be applied as high-sensitivity micromagnetic sensors for use in computers, electric power equipment, automobiles, home domestic equipment, portable equipment and the like.

Examples of the materials known to show the GMR effect include a metal artificial lattice including a multilayer film having a ferromagnetic layer (for example, a permalloy layer) and a non-magnetic layer (for example, a Cu, Ag or Au layer) or a multilayer film with a four-layer structure (so-called “spin valve”) having an antiferromagnetic layer, a ferromagnetic layer (a fixed layer), a non-magnetic layer and a ferromagnetic layer (a free layer); a metal-metal-based nano-granular material including nanometer-sized fine particles including a ferromagnetic metal (for example, permalloy) and a grain boundary phase including a non-magnetic metal (for example, Cu, Ag or Au); a tunnel junction film causing an MR (magnetoresistive) effect by a spin-dependent tunneling effect; and a metal-insulator-based nano-granular material including nanometer-sized fine particles including a ferromagnetic metal alloy and a grain boundary phase including a non-magnetic insulating material.

Among those materials, multilayer films represented by the spin valve are generally characterized in that they are high in sensitivity in a low magnetic field. However, it is necessary to laminate thin films including various materials with a high degree of accuracy. Therefore, the multilayer films are so poor in stability or yield that there is a limit for restricting the manufacturing cost. Accordingly, it is considered that such multilayer films can be exclusively used only for high-value added devices (for example, a magnetic head for a hard disk), but is difficult to be applied to magnetic sensors which are inevitably exposed to competition in price with AMR sensors or Hall sensors low in unit price. Further, in each of the multilayer films, diffusion may occur easily between layers of the multilayer film and the GMR effect may disappear easily. Thus, the multilayer films have a significant drawback of poor heat resistance.

On the other hand, nano-granular materials can be generally easily manufactured and have good reproducibility. Accordingly, when the nano-granular materials are applied to magnetic sensors, the cost of the magnetic sensors can be decreased. In particular, the metal-insulator-based nano-granular materials are advantageous in that:

(1) the metal-insulator-based nano-granular materials show a high MR ratio exceeding 10% at room temperature when a composition thereof is optimized;
(2) the metal-insulator-based nano-granular materials have an outstandingly high electrical resistivity p, so that microminiaturization and low power consumption can be realized simultaneously in the magnetic sensors; and
(3) the metal-insulator based nano-granular materials can be used even under a high temperature environment unlike the spin valve film containing an antiferromagnetic film which is poor in heat resistance. In spite of such advantages, the metal-insulator-based nano-granular materials have a problem that magnetic field sensitivity is extremely low in a low magnetic field. Accordingly, in such a case, yokes made of a soft magnetic material are disposed at both ends of a giant magnetoresistive film (hereinafter also referred to as GMR film) to increase the magnetic field sensitivity of the GMR film.

Generally, when a direction of a magnetic field is detected by a magnetic sensor showing an even function characteristic with respect to a change of the magnetic field, a bias magnetic field is applied to the magnetic sensor. In addition, in order to apply the bias magnetic field to the magnetic sensor, a coil or a permanent magnet is typically disposed outside the magnetic sensor. Alternatively, in order to miniaturize a sensor device, a thin-film magnet is often formed in a lower layer portion or an upper layer portion of a sensor element.

For example, Patent Document 1 discloses a magnetic sensor in which a multilayer film including a soft magnetic thin film and a hard magnetic thin film have been disposed at both ends of a giant magnetoresistive thin film.

Patent Document 1 suggests that, when a magnetic field generated by the hard magnetic thin film is applied as a bias magnetic field to the magnetic sensor in which a change in electrical resistance does not depend on the direction of a magnetic field, magnitude and polarity of an external magnetic field can be detected concurrently.

In addition, Patent Document 2 discloses a magnetic impedance effect element in which a laminate provided with an antiferromagnetic film and a magnetization direction fixed film has been fixedly attached through an insulating film to one surface of a substrate in which a belt-like magnetic thin film with high magnetic permeability has been formed.

Patent Document 2 suggests that:

(a) the magnetization direction fixed film is coupled with the antiferromagnetic film by magnetic exchange coupling so that the magnetization direction of the magnetization direction fixed film can be fixed in a longitudinal direction of the magnetic thin film; and
(b) as a result, a bias magnetic field can be applied to the magnetic thin film in its longitudinal direction.

When a coil is used for applying a bias magnetic field to the magnetic sensor, it is necessary to apply an electric current to the coil. Therefore, there are problems such as (1) necessity of a dedicated power supply and a dedicated circuit, (2) difficulty in miniaturization, (3) large electric power consumption, etc.

When a permanent magnet is used, electric power is not consumed. However, the magnetic field changes in accordance with a distance from the magnet. It is therefore necessary to decide the attachment position of the magnet accurately. Thus, there is a problem that manufacturing becomes difficult.

On the other hand, when a thin-film magnet is used, the thin-film magnet can be manufactured in a similar fine processing process to that of the sensor element. It is therefore possible to decide the attachment position of the thin-film magnet comparatively accurately. However, there is a problem that the magnetic force of the thin-film magnet is too weak to provide a sufficient magnetic field easily.

Patent Document 1: JP-A-2003-078187

Patent Document 2: JP-A-2002-043648

### SUMMARY OF THE INVENTION

An object of the present invention is to provide a thin-film magnetic sensor capable of applying a bias magnetic field to a high-sensitivity element accurately without causing increase in electric power consumption or increase in element size.

Another object of the present invention is to increase magnitude of the bias magnetic field relatively in the thin-film magnetic sensor.

Namely, the present invention relates to the following items (1) to (5).

(1) A thin-film magnetic sensor including:

a substrate;

a high-sensitivity element which is formed on the substrate and detects a change in an external magnetic field;

a low-sensitivity element which is formed on the substrate and connected in series with the high-sensitivity element, and which compensates fluctuation of a resistance value caused by a temperature change;

a thin-film magnet which applies a bias magnetic field to the high-sensitivity element; and

an insulating film (A) inserted between the high-sensitivity element and the thin-film magnet,

in which the high-sensitivity element includes: a GMR film (A) having a giant magnetoresistive effect; and a pair of thin-film yokes (A) made of a soft magnetic material and electrically connected to both ends of the GMR film (A),

the low-sensitivity element includes: a GMR film (B) having a giant magnetoresistive effect; and a pair of thin-film yokes (B) made of a soft magnetic material and electrically connected to both ends of the GMR film (B), and

the thin-film magnet is disposed at least just below the GMR film (A) on the substrate side or just above the GMR film (A) on a side opposite to the substrate side.

(2) The thin-film magnetic sensor according to (1), in which the high-sensitivity element and the low-sensitivity element are disposed on one and the same plane.
(3) The thin-film magnetic sensor according to (1) or (2), in which a thickness (t_{M}) of the thin-film magnet is not smaller than 0.1 μm and not larger than 5 μm.
(4) The thin-film magnetic sensor according to any one of (1) to (3), in which a length (L_{M}) of the thin-film magnet in a magnetic sensitive direction is not smaller than gi and not larger than 1.1L, in which gₗ designates a length of the GMR film (A) in the magnetic sensitive direction, and L designates a total length of the high-sensitivity element in the magnetic sensitive direction.
(5) The thin-film magnetic sensor according to any one of (1) to (4), in which a width (W_{M}) of the thin-film magnet is not smaller than 0.9W, in which W designates a width of each of the thin-film yokes (A).

In a thin-film magnetic sensor in which a high-sensitivity element and a low-sensitivity element have been connected in series, a thin-film magnet is inserted at least just above or just below a GMR film (A) through an insulating film (A), so that a bias magnetic field can be applied to the high-sensitivity element accurately without causing increase in electric power consumption or increase in element size. In addition, the size of the thin-film magnet is optimized so that a relatively large bias magnetic field can be applied to the high-sensitivity element.

### BRIEF DESCRIPTION OF THE DRAWING

FIGS. 1A and 1B are a plan view (FIG. 1A) of a thin-film magnetic sensor according to a first embodiment of the present invention, and a sectional view (FIG. 1B) thereof taken on line A-A′.

FIGS. 2A and 2B are a plan view (FIG. 2A) of a thin-film magnetic sensor according to a second embodiment of the present invention, and a sectional view (FIG. 2B) thereof taken on line A-A′.

FIGS. 3A and 3B are a plan view (FIG. 3A) of a thin-film magnetic sensor according to a third embodiment of the present invention, and a sectional view (FIG. 3B) thereof taken on line A-A′.

FIGS. 4A and 4B are a plan view (FIG. 4A) of a thin-film magnetic sensor according to a fourth embodiment of the present invention, and a sectional view (FIG. 4B) thereof taken on line A-A′.

FIGS. 5A to 5C are plan views of thin-film magnetic sensors with thin-film magnets different in width.

FIG. 6 is a graph showing MR curves of the thin-film magnetic sensors shown in FIGS. 5A to 5C.

FIG. 7 is a graph showing magnet width/yoke width ratio dependency of a bias magnetic field.

FIG. 8 is a graph showing MR curves of thin-film magnetic sensors different in yoke length, magnet length and magnet width.

FIGS. 9A and 9B are a graph (FIG. 9A) showing a relation between a magnet width and a bias magnetic field, and a graph (FIG. 9B) showing a relation between a magnet width/yoke width ratio and a bias magnetic field.

FIGS. 10A and 10B are a graph (FIG. 10A) showing a relation between a magnet length and a bias magnetic field, and a graph (FIG. 10B) showing a relation between a magnet length/total length ratio and a bias magnetic field.

FIG. 11 is a graph showing a relation between a magnet thickness and a bias magnetic field.

### DETAILED DESCRIPTION OF THE INVENTION

One embodiment of the present invention will be described in detail below.

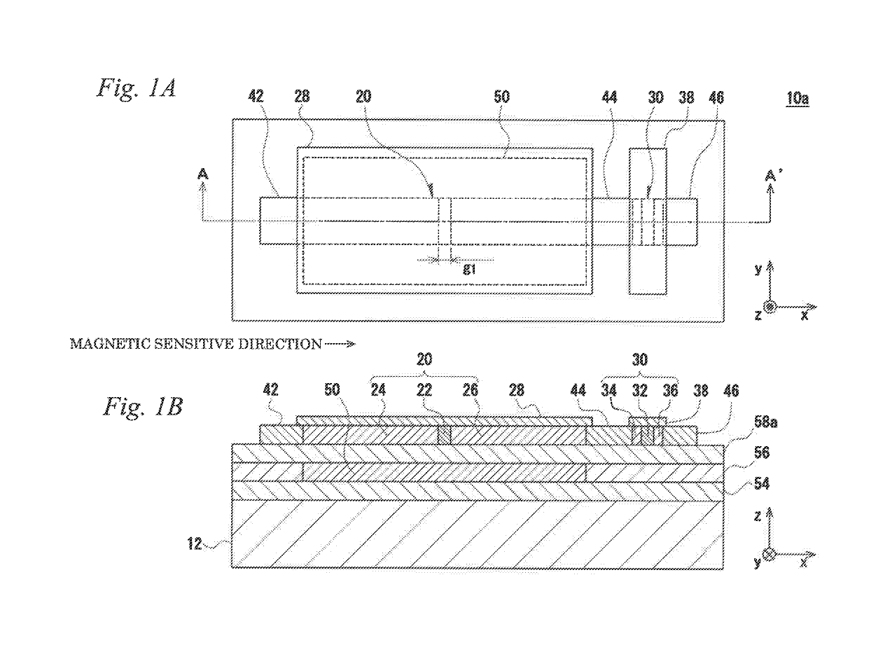

1. Thin-Film Magnetic Sensor (1) FIGS. 1A and 1B show a plan view of a thin-film magnetic sensor according to a first embodiment of the present invention, and a sectional view thereof taken on line A-A′. In FIGS. 1A and 1B, a thin-film magnetic sensor 10a includes:

a substrate 12;

a high-sensitivity element 20 which is formed on the substrate 12 and detects a change in an external magnetic field;

a low-sensitivity element 30 which is formed on the substrate 12 and connected in series with the high-sensitivity element 20, and which compensates fluctuation of a resistance value caused by a temperature change;

a thin-film magnet 50 which applies a bias magnetic field to the high-sensitivity element 20; and

an insulating film (A) 58a inserted between the high-sensitivity element 20 and the thin-film magnet 50.

### 1.1. Substrate

The substrate 12 is provided so that the high-sensitivity element 20, the low-sensitivity element 30 and the thin-film magnet 50 can be formed on a surface thereof. The material or shape of the substrate is not limited especially, but a most suitable material and a most suitable shape can be selected in accordance with a purpose.

### 1.2. High-Sensitivity Element

The high-sensitivity element 20 includes a GMR film (A) 22 having a giant magnetoresistive effect, and a pair of thin-film yokes (A) 24 and 26 made of a soft magnetic material and electrically connected to both ends of the GMR film (A) 22. A surface of the high-sensitivity element 20 is covered with a protective film 28. Further, an electrode 42 for extracting an output is bonded to one end of the high-sensitivity element 20, and an electrode 44 to be coupled with the low-sensitivity element 30 is bonded to the other end thereof.

### 1.2.1. GMR Film (A)

The GMR film (A) 22 is used for sensing a change in an external magnetic field as a change in electric resistance R and, as a result, detecting it as a change in voltage. The GMR film (A) 22 is made of a material having a giant magnetoresistivite (GMR) effect. In order to detect the change in the external magnetic field at high sensitivity, it is preferable that the absolute value of the MR ratio of the GMR film (A) 22 is larger. Specifically, the absolute value of the MR ratio of the GMR film (A) 22 is preferably 5% or more, and more preferably 10% or more.

Further, the GMR film (A) 22 is electrically connected directly to the thin-film yokes 24 and 26. Therefore, a GMR film having higher electrical resistivity ρ than that of each thin-film yoke 24, 26 is used as the GMR film (A) 22. In General, when the electrical resistivity ρ of the GMR film (A) 22 is excessively low, the ratio of electric resistance in wiring or the like to the total electric resistance of the sensor is relatively increased. As a result, the MR ratio is reduced unfavorably. On the other hand, when the electrical resistivity ρ of the GMR film (A) 22 is excessively high, noises increase and it becomes difficult to detect the change in the external magnetic field as the change in voltage.

Specifically, the electrical resistivity ρ of the GMR film (A) 22 is preferably not lower than 10³ μΩcm and not higher than 10¹² μΩcm, and more preferably not lower than 10⁴ μΩcm and not higher than 10¹¹ μΩcm.

Various materials satisfy such conditions. Of these, the metal-insulator-based nano-granular materials described above are particularly suitable. The metal-insulator-based nano-granular materials have high MR ratio and high electrical resistivity p. In addition, the MR ratio does not fluctuate largely by a slight compositional variation. Accordingly, there is an advantage that a thin film having stable magnetic characteristics can be manufactured with good reproducibility and at low cost.

Specifically, examples of the metal-insulator-based nano-granular materials used for the GMR film (A) 22 include:

(1) oxide-based nano-granular alloys such as Co—Y₂O₃-based nano-granular alloys, Co—Al₂O₃-based nano-granular alloys, Co—Sm₂O₃-based nano-granular alloys, Co—Dy₂O₃-based nano-granular alloys and FeCo—Y₂O₃-based nano-granular alloys; and (2) fluoride-based nano-granular alloys such as Fe—MgF₂, FeCo—MgF₂, Fe—CaF₂ and FeCo—AlF₃.

1.2.2. Thin-Film Yokes (A)

The thin-film yokes (A) 24 and 26 are opposed to each other through a gap, and the GMR film (A) 22 is electrically connected to the thin-film yokes (A) 24 and 26 in the gap or at the vicinity of the gap.

The terms “the vicinity of the gap” herein means a region influenced by a large amplified magnetic field generated at leading edges of the thin-film yokes (A) 24 and 26. The magnetic field generated between the thin-film yokes (A) 24 and 26 becomes largest in the gap. It is therefore most preferable to form the GMR film (A) 22 in the gap. However, this means that when the magnetic field acting on the GMR film (A) 22 is practically sufficiently large, the GMR film (A) 22 may be entirely or partially out of the gap (for example, on the upper surface side or the lower surface side of the thin-film yokes (A) 24 and 26).

The thin-film yokes (A) 24 and 26 are used for enhancing the magnetic field sensitivity of the GMR film (A) 22. The thin-film yokes (A) 24 and 26 are made of a soft magnetic material. In order to obtain high magnetic field sensitivity to a weak magnetic field, it is preferable to use a material having high magnetic permeability pt and/or high saturation magnetization Ms for the thin-film yokes (A) 24 and 26. In addition, it is preferable that the material of the thin-film yokes (A) 24 and 26 has no magnetic saturation in a range of an external magnetic field to be used. On the other hand, it is preferable that the magnetic permeability μ of the soft magnetic material is higher. For example, the magnetic permeability μ is preferably 5,000 or more.

Specific examples of soft magnetic materials satisfying such conditions may include:

(a) 40-90% Ni—Fe alloys, Fe₇₄Si₉Al₇, Fe₁₂Ni₈₂Nb₆, FC_{75.6}Si_{13.2}B_{8.5}Nb_{1.9}Cu_{0.8}, Fe₈₃Hf₆C₁₁, Fe_{8.5}Zr₁₀B₅ alloys, Fe₉₃Si₃N₄ alloys and Fe₇₁B₁₁N₁₈ alloys;
(b) 40-90% Ni—Fe alloy/SiO₂ multilayer films;
(c) Fe_{71.3}Nd_{9.6}O_{19.1} nano-granular alloys, Co₇₀Al₁₀O₂ nano-granular alloys and Co₆₅Fe₅Al₁₀O₂₀ nano-granular alloys;
(d) Co₃₅Fe₃₅Mg₁₀F₂₀ nano-granular alloys; and
(e) Co₈₈Nb₆Zr₆ amorphous alloys, and (Co₉₄Fe₆)₇₀Si₁₅B₁₅ amorphous alloys; etc.

### 1.2.3 Shape and Size of High-Sensitivity Element

The high-sensitivity element 20 is used for detecting a change in an external magnetic field. It is therefore preferable that the magnetic field sensitivity of the high-sensitivity element 20 in a magnetic sensitive direction is larger.

The terms “magnetic sensitive direction” herein means a direction in which the external magnetic field is applied when the magnetic field sensitivity of the GMR film (A) 22 is maximized.

The shape and size of each part of the high-sensitivity element 20 give influence to the magnetic field sensitivity in the magnetic sensitive direction. Generally, as gap length (length of the GMR film (A) 22 in the magnetic sensitive direction) gi is shorter, leakage flux is reduced to make the sensitivity higher. In addition, as length of each thin-film yoke (A) 24, 26 in the magnetic sensitive direction is increased, a demagnetization coefficient of the thin-film yoke (A) 24, 26 is reduced to make the sensitivity higher. It is therefore preferable that a most suitable shape and a most suitable size are selected as the shape and size of each part of the high-sensitivity element 20 in order to obtain intended sensitivity.

### 1.2.4. Protective Film

The protective film 28 is used for protecting the high-sensitivity element 20 from moisture contained in the atmosphere. As long as the protective film 28 can show such a function, the material and thickness of the protective film 28 are not limited especially. For example, alumina, SiO₂, Si₃N₄, etc. can be used for the protective film 28.

### 1.3. Low-Sensitivity Element

The low-sensitivity element 30 includes a GMR film (B) 32 having a giant magnetoresistive effect, and a pair of thin-film yokes (B) 34 and 36 made of a soft magnetic material and electrically connected to both ends of the GMR film (B) 32. A surface of the low-sensitivity element 30 is covered with a protective film 38. Further, the electrode 44 to be coupled with the high-sensitivity element 20 is bonded to one end of the low-sensitivity element 30, and an electrode 46 for extracting an output is bonded to the other end thereof.

The terms “low-sensitivity element 30” herein means an element whose magnetic field sensitivity is lower than that of the high-sensitivity element 20.

### 1.3.1. GMR Film (B)

The material of the GMR film (B) 32 may be a different material from that of the GMR film (A) 22 of the high-sensitivity element 20. It is, however, preferable that the GMR film (B) 32 is made of the same material as the GMR film (A) 22. When the same material is used for the GMR film (B) 32 and the GMR film (A) 22, both the GMR films can be formed concurrently in one step. It is therefore possible to reduce the manufacturing cost. In addition, when the same material is used, both the GMR films can show the same resistance change quantity to temperature. Therefore, there is an advantage that midpoint potential is not shifted by a temperature change when a bridge circuit is formed.

The other points as to the material of the GMR film (B) 32 are similar to those of the GMR film (A) 22, and description thereof will be omitted.

### 1.3.2. Thin-Film Yokes (B)

The material of the thin-film yokes (B) 34 and 36 may be a different material from or the same material as that of the thin-film yokes (A) 24 and 26 of the high-sensitivity element 20. When the same material is used for the thin-film yokes (B) 34 and 36 and the thin-film yokes (A) 24 and 26, both the thin-film yokes can be formed concurrently in one step. It is therefore possible to reduce the manufacturing cost.

The other points as to the material of the thin-film yokes (B) 34 and 36 are similar to those of the thin-film yokes (A) 24 and 26, and description thereof will be omitted.

### 1.3.3. Magnetic Field Sensitivity

The low-sensitivity element 30 is used for compensating fluctuation of a resistance value caused by a temperature change. It is therefore preferable that the magnetic field sensitivity of the low-sensitivity element 30 is lower.

Methods for reducing the magnetic field sensitivity of the low-sensitivity element 30 may include a method for reducing the magnetic field sensitivity of the low-sensitivity element 30 itself, and a method for reducing the magnetic field sensitivity of the low-sensitivity element 30 indirectly using a magnetic shield. However, it is difficult to block the external magnetic field perfectly only by the magnetic shield, and a step of producing the magnetic shield must be added. It is therefore preferred to reduce the magnetic field sensitivity of the low-sensitivity element 30 itself.

When the size of each part of the low-sensitivity element 30 is optimized, the magnetic field sensitivity of the low-sensitivity element 30 can be reduced to ½ or lower of that of the high-sensitivity element 20. The magnetic field sensitivity of the low-sensitivity element 30 is preferably ⅕ or lower of that of the high-sensitivity element 20, and more preferably 1/10 or lower of that of the high-sensitivity element 20.

The terms “magnetic field sensitivity” herein means easiness with which electrical resistivity of an element changes in accordance with a change in an external magnetic field (strictly, an external magnetic field of a component in a magnetic sensitive direction of the element). Accordingly, the terms “magnetic field sensitivity is low” means a characteristic that the electrical resistivity hardly changes in spite of a large change in the external magnetic field. On the contrary, the terms “magnetic field sensitivity is high” means a characteristic that the electrical resistivity changes easily even in a slight change in the external magnetic field. In the present invention, the both are used so that the magnetic sensor can show high performance in spite of a change in environmental temperature.

A method for changing the magnetic field sensitivity is not limited especially. Examples of the method include a method of changing a thin-film yoke length (length in a parallel direction to the magnetic sensitive direction) and a method of changing an aspect ratio represented by thin-film yoke length/thin-film yoke width.

As the length of each thin-film yoke 34, 36 is shorter, the magnetic field sensitivity is reduced. It is therefore preferable that the length of each thin-film yoke 34, 36 of the low-sensitivity element 30 is shorter than the length of each thin-film yoke 24, 26 of the high-sensitivity element 20.

Further, as the aspect ratio is smaller, the magnetic field sensitivity is reduced. It is therefore preferable that the aspect ratio of the low-sensitivity element 30 is smaller than the aspect ratio of the high-sensitivity element 20.

Of the aforementioned methods, only one may be used. However, when some methods are used, the magnetic field sensitivity can be changed more easily. Therefore, all the aforementioned methods are used in FIGS. 1A and 1B.

### 1.3.4. Protective Film

The protective film 38 is used for protecting the low-sensitivity element 30 from moisture contained in the atmosphere. The details of the protective film 38 are similar to those of the protective film 28, and description thereof will be omitted.

### 1.4. Thin-Film Magnet

The terms “thin-film magnet” in the present invention means a magnet produced by a thin-film process. The thickness of the thin-film magnet is not limited especially, but is preferably not larger than 30 μm. It is preferable that the thin-film magnet 50 satisfies the following conditions.

### 1.4.1. Position of Thin-Film Magnet

The thin-film magnet 50 is used for applying a bias magnetic field to the high-sensitivity element 20. The thin-film magnet 50 may be disposed above the high-sensitivity element 20 (that is, on the surface side, i.e., on a side opposite to the substrate 12 side), or may be disposed below the high-sensitivity element 20 (that is, on the substrate 12 side).

Generally the thin-film magnet 50 often requires heat treatment in order to obtain a high magnetic property. In this case, when the thin-film magnet 50 is disposed above the high-sensitivity element 20, the high-sensitivity element 20 may be also heated during the heat treatment of the thin-film magnet 50 so that the magnetic property of the high-sensitivity element 20 can be degraded. It is therefore preferable that the thin-film magnet is disposed below the high-sensitivity element 20 (that is, on the substrate 12 side).

Further, in order to apply a large bias magnetic field to the high-sensitivity element 20 by use of a small amount of the thin-film magnet 50, the thin-film magnet 50 must be disposed at least just below the GMR film (A) 22 (that is, on the substrate 12 side) or just above the GMR film (A) 22 (that is, on the surface side, i.e., on the side opposite to the substrate 12 side).

The thin-film magnet 50 may be disposed symmetrically around the GMR film (A) 22 in an x-direction and/or a y-direction, or may be disposed asymmetrically. Even when the thin-film magnet 50 is disposed asymmetrically with respect to the GMR film (A) 22, a large bias magnetic field can be applied to the high-sensitivity element 20 only if the thin-film magnet 50 is disposed at least just below or just above the GMR film (A) 22.

Incidentally, in the present invention, no thin-film magnet is disposed above or below the low-sensitivity element 30. When thin-film magnets 50 having equivalent thicknesses were disposed for both the high-sensitivity element 20 and the low-sensitivity element 30, a larger bias magnetic field would act on the low-sensitivity element 30 so that the resistance value of the GMR film (B) 32 could change more largely to shift the midpoint potential largely.

### 1.4.2. Size of Thin-Film Magnet

The size of the thin-film magnet 50 gives great influence to the bias magnetic field applied to the high-sensitivity element 20. It is therefore preferable that most suitable values are selected as dimensions of the thin-film magnet 50 in accordance with a purpose.

### A. Thickness

When thickness (t_{M}: length in z-direction) of the thin-film magnet 50 is too small, a sufficiently large bias magnetic field cannot be applied to the high-sensitivity element 20. It is therefore preferable that the thickness (t_{M}) of the thin-film magnet is not smaller than 0.1 μm. The thickness (t_{M}) of the thin-film magnet is more preferably not smaller than 1 μm.

On the contrary, when thickness (t_{M}) of the thin-film magnet is too large, the elongated time required for film formation and the increased amount of a raw material lead to increase in cost. In addition, increase in film thickness may lead to warpage or cracking in the substrate due to film stress. It is therefore preferable that the thickness (t_{M}) of the thin-film magnet is not larger than 5 μm.

### B. Length in Magnetic Sensitive Direction

The thin-film magnet 50 is disposed so that an N pole of the thin-film magnet 50 can be positioned at one end of the high-sensitivity element 20 in the magnetic sensitive direction thereof, and an S pole of the thin-film magnet 50 can be positioned at the other end thereof. Magnetic flux leaking out from the N pole draws a loop and flows into the S pole. When the high-sensitivity element 20 is placed within the loop, a suitably large bias magnetic field can be applied to the high-sensitivity element 20.

However, when length (L_{M}: length in x-direction) of the thin-film magnet 50 in the magnetic sensitive direction is too short, a sufficiently large bias magnetic field cannot be applied to the high-sensitivity element 20. It is therefore preferable that the length L_{M} is not smaller than gₗ. A guide of gi is about 1 μm. The length L_{M} is more preferably not smaller than 5 μm. Here, “gₗ” is a length (gap length) of the GMR film (A) 22 in the magnetic sensitive direction.

Generally, as the length L_{M} increases, the bias magnetic field increases. However, when the length L_{M} exceeds a certain critical value, the bias magnetic field drops down suddenly. It is therefore preferable that the length L_{M} is not larger than 1.1L. The length L_{M} is more preferably not larger than 1.0L. Here, “L” is a total length (=length of GMR film (A) 22 in magnetic sensitive direction+length of thin-film yoke (A) 24 in magnetic sensitive direction+length of thin-film yoke (A) 26 in magnetic sensitive direction) of the high-sensitivity element 20 in the magnetic sensitive direction.

### C. Width

When width (W_{M}: length in y-direction) of the thin-film magnet 50 is too short, a sufficiently large bias magnetic field cannot be applied to the high-sensitivity element 20. It is therefore preferable that the width W_{M} is not smaller than 0.9W. The width W_{M} is more preferably not smaller than 5W. Here, “W” is a width of each thin-film yoke (A) 24, 26.

On the other hand, even when the width W_{M} is increased to be larger than necessary, there is no difference in effect but it is meaningless. It is therefore preferable that the width W_{M} is not larger than 20W. The width W_{M} is more preferably not larger than 10W.

Incidentally, the “width” in the present invention means a maximum value of the width of the thin-film magnet 50 or each thin-film yoke (A) 24, 26.

### 1.5. Insulating Film (A)

The insulating film (A) 58a is used for electrically insulating the high-sensitivity element 20 and the thin-film magnet 50 from each other. The insulating film (A) 58a is inserted between the high-sensitivity element 20 and the thin-film magnet 50. When the insulating film (A) 58a were absent between the high-sensitivity element 20 and the thin-film magnet 50 disposed just below or just above the high-sensitivity element 20, the high-sensitivity element 20 would be short-circuited. It is therefore necessary to put the insulating film (A) 58a between the high-sensitivity element 20 and the thin-film magnet 50.

Generally, as the thickness of the insulating film (A) 58a is reduced, the high-sensitivity element 20 is short-circuited more easily. On the contrary, when the insulating film (A) 58a is too thick, the bias magnetic field acting on the GMR film (A) 22 becomes excessively small. It is therefore preferable that most suitable thickness is selected as the thickness of the insulating film (A) 58a in consideration of this point. Specifically, the thickness of the insulating film (A) 58a is preferably 0.5 μm to 2 μm. Any non-magnetic insulator may be used as the material of the insulating film (A) 58a. Examples of the material of the insulating film (A) 58a include alumina, SiO₂, Si₃N₄, MgO, MgF₂, etc.

The shape of the insulating film (A) 58a or any other dimension thereof than the thickness is not limited especially. In the example shown in FIGS. 1A and 1B, a non-magnetic film (A) 54 is formed all over a surface of the substrate 12. In addition, the thin-film magnet 50 is formed on a surface of the non-magnetic film (A) 54, and a non-magnetic film (B) 56 is formed around the thin-film magnet 50. The non-magnetic film (A) 54 and the non-magnetic film (B) 56 are used for adjusting the positions of the high-sensitivity element 20 and the low-sensitivity element 30 in the z-direction. Therefore, any non-magnetic substance may be used for the non-magnetic film (A) 54 and the non-magnetic film (B) 56, which do not have to be insulators. In addition, the non-magnetic film (A) 54 and the non-magnetic film (B) 56 may be made of the same kind of material, or may be made of different kinds of materials.

Further, the insulating film (A) 58a is formed all over the surfaces of the thin-film magnet 50 and the non-magnetic film (B) 56. The high-sensitivity element 20 and the low-sensitivity element 30 are formed on the surface of the insulating film (A) 58a, and the high-sensitivity element 20 and the low-sensitivity element 30 are disposed on one and the same plane.

As will be described later, the high-sensitivity element 20 and the low-sensitivity element 30 cannot be disposed on one and the same plane in some method for forming the insulating film (A) 58a and the thin-film magnet 50. In this case, due to a difference in height between the high-sensitivity element 20 and the low-sensitivity element 30, a focus position may be shifted in an exposure step during fine processing. Due to the focus shift, the sizes of the high-sensitivity element 20 and the low-sensitivity element 30 may be varied to increase a deviation and a variation of the resistance value.

On the other hand, when the non-magnetic film (A) 54, the non-magnetic film (B) 56, the insulating film (A) 58a and the thin-film magnet 50 are disposed so that the high-sensitivity element 20 and the low-sensitivity element 30 can be disposed on one and the same plane, the deviation and the variation of the resistance value can be reduced.

### 2. Thin-Film Magnetic Sensor (2)

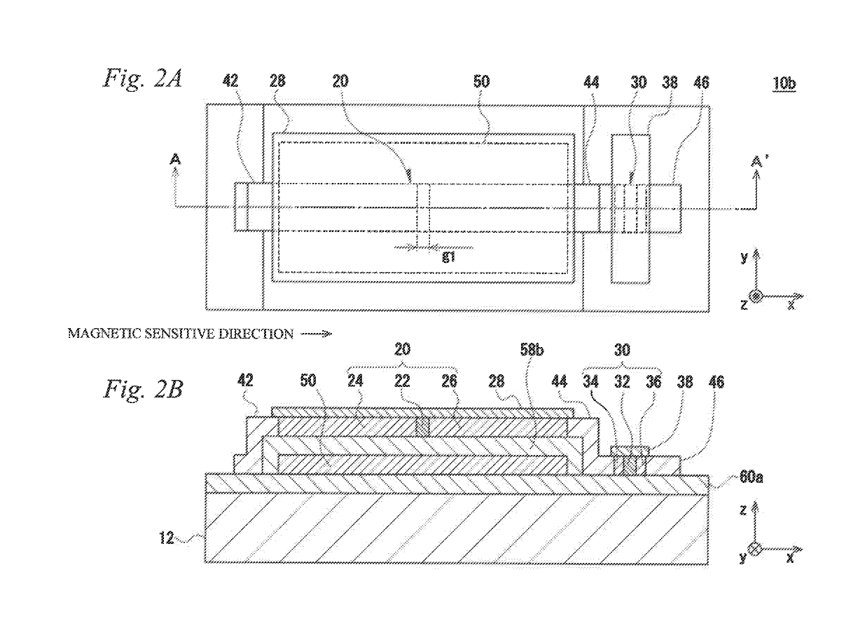

FIGS. 2A and 2B show a plan view of a thin-film magnetic sensor according to a second embodiment of the present invention, and a sectional view thereof taken on line A-A′. In FIGS. 2A and 2B, a thin-film magnetic sensor 10b includes:

a substrate 12;

a high-sensitivity element 20 which is formed on the substrate 12 and detects a change in an external magnetic field;

a low-sensitivity element 30 which is formed on the substrate 12 and connected in series with the high-sensitivity element 20, and which compensates fluctuation of a resistance value caused by a temperature change;

a thin-film magnet 50 which applies a bias magnetic field to the high-sensitivity element 20; and

an insulating film (A) 58b inserted between the high-sensitivity element 20 and the thin-film magnet 50.

In the thin-film magnetic sensor 10b shown in FIGS. 2A and 2B, an insulating film (B) 60a is formed all over a surface of the substrate 12, and the thin-film magnet 50 is formed on a surface of the insulating film (B) 60a. In addition, the insulating film (A) 58b is formed to cover only a surface and side faces of the thin-film magnet 50. Further, the high-sensitivity element 20 is formed on a surface of the insulating film (A) 58b, and the low-sensitivity element 30 is formed on the surface of the insulating film (B) 60a. Therefore, the high-sensitivity element 20 and the low-sensitivity element 30 are not disposed on the same plane. At this point, the second embodiment is different from the first embodiment. The insulating film (A) 58b and the insulating film (B) 60a may be made of the same kind of material, or may be made of different kinds of materials.

The other points are similar to those of the first embodiment, and description thereof will be omitted.

In the thin-film magnetic sensor 10b shown in FIGS. 2A and 2B, the high-sensitivity element 20 and the low-sensitivity element 30 are not disposed on the same plane. Accordingly, there is a concern that the sizes of the high-sensitivity element 20 and the low-sensitivity element 30 may be varied during fine processing. However, if especially high accuracy is not required, the size and the polarity of the external magnetic field can be known correctly to some extent in spite of such a structure.

### 3. Thin-Film Magnetic Sensor (3)

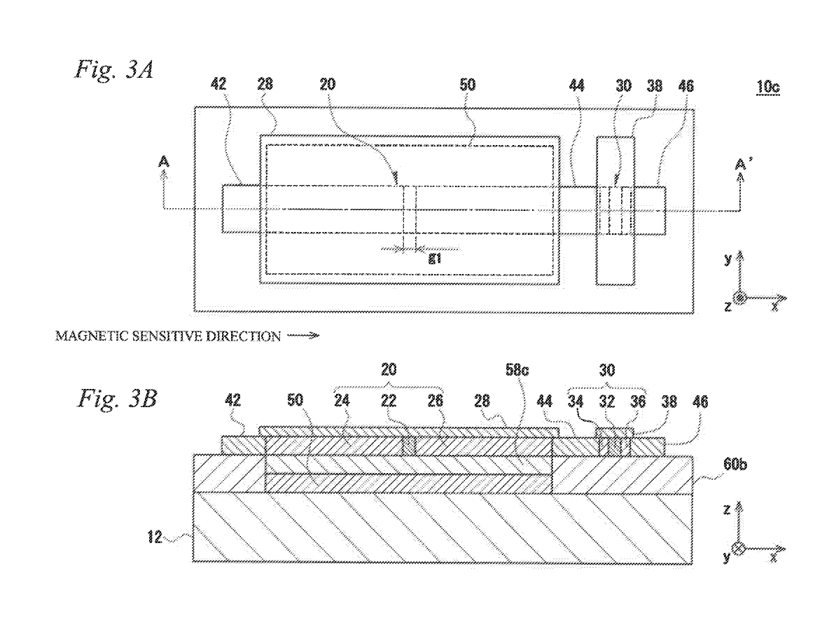

FIGS. 3A and 3B show a plan view of a thin-film magnetic sensor according to a third embodiment of the present invention, and a sectional view thereof taken on line A-A′. In FIGS. 3A and 3B, a thin-film magnetic sensor 10c includes:

a substrate 12;

a high-sensitivity element 20 which is formed on the substrate 12 and detects a change in an external magnetic field;

a low-sensitivity element 30 which is formed on the substrate 12 and connected in series with the high-sensitivity element 20, and which compensates fluctuation of a resistance value caused by a temperature change;

a thin-film magnet 50 which applies a bias magnetic field to the high-sensitivity element 20; and

an insulating film (A) 58c inserted between the high-sensitivity element 20 and the thin-film magnet 50.

In the thin-film magnetic sensor 10c shown in FIGS. 3A and 3B, the thin-film magnet 50 is formed on a surface of the substrate 12, and the insulating film (A) 58c is formed only on a surface of the thin-film magnet 50. In addition, an insulating film (B) 60b is formed around the thin-film magnet 50 and the insulating film (A) 58c. The insulating film (B) 60b has a thickness substantially equal to the total thickness of the thin-film magnet 50 and the insulating film (A) 58c. At this point, the third embodiment is different from the first embodiment. The high-sensitivity element 20 is formed on the insulating film (A) 58c, and the low-sensitivity element 30 is formed on the insulating film (B) 60b. Therefore, the high-sensitivity element 20 and the low-sensitivity element 30 are disposed on one and the same plane.

The other points are similar to those of the first embodiment, and description thereof will be omitted.

### 4. Thin-Film Magnetic Sensor (4)

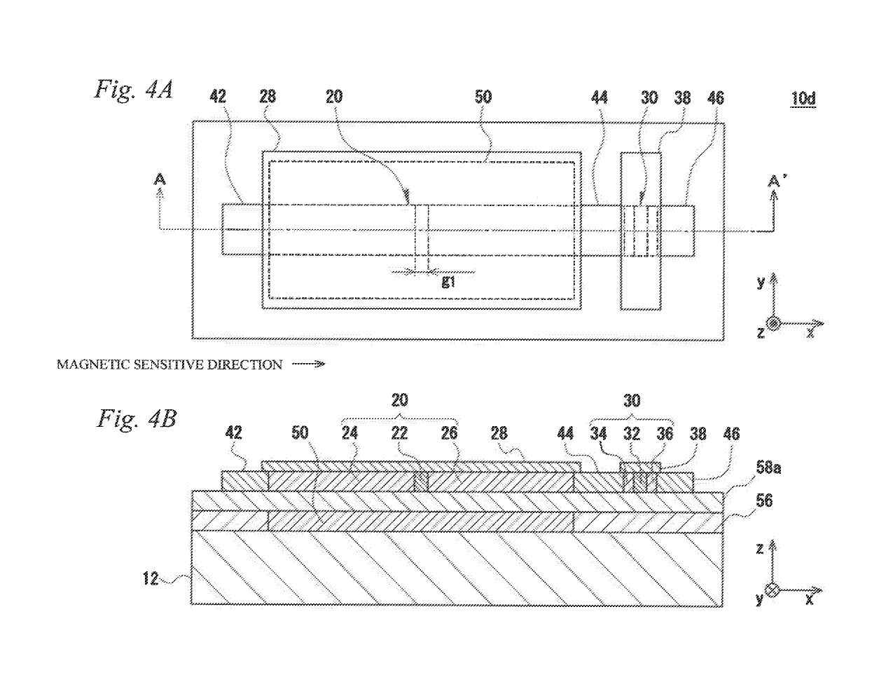

FIGS. 4A and 4B show a plan view of a thin-film magnetic sensor according to a fourth embodiment of the present invention, and a sectional view thereof taken on line A-A′. In FIGS. 4A and 4B, a thin-film magnetic sensor 10d includes:

a substrate 12;

a high-sensitivity element 20 which is formed on the substrate 12 and detects a change in an external magnetic field;

a low-sensitivity element 30 which is formed on the substrate 12 and connected in series with the high-sensitivity element 20, and which compensates fluctuation of a resistance value caused by a temperature change;

a thin-film magnet 50 which applies a bias magnetic field to the high-sensitivity element 20; and

an insulating film (A) 58a inserted between the high-sensitivity element 20 and the thin-film magnet 50.

In the thin-film magnetic sensor 10d shown in FIGS. 4A and 4B, the thin-film magnet 50 is formed on a surface of the substrate 12, and a non-magnetic film (B) 56 is formed around the thin-film magnet 50. The non-magnetic film (B) 56 has a thickness substantially equal to that of the thin-film magnet 50. In addition, the insulating film (A) 58a is formed all over a surface of the thin-film magnet 50 and a surface of the non-magnetic film (B) 56. That is, the thin-film magnetic sensor 10d does not have the non-magnetic film (A) 54. At this point, the fourth embodiment is different from the first embodiment. The high-sensitivity element 20 and the low-sensitivity element 30 are formed on the insulating film (A) 58a. Therefore, the high-sensitivity element 20 and the low-sensitivity element 30 are disposed on one and the same plane.

The other points are similar to those of the first embodiment, and description thereof will be omitted.

### 3. Method for Manufacturing Thin-Film Magnetic Sensor

Each thin-film magnetic sensor 10a to 10d according to the present invention can be manufactured in such a manner that thin films having predetermined compositions are laminated on a surface of a substrate 12 in a predetermined order. The laminating conditions of each thin film are not limited especially, but it is preferable that most suitable conditions are selected in accordance with the composition of the thin film.

### 4. Operation

Generally, when a direction of a magnetic field is detected by a magnetic sensor having an even function characteristic with respect to a change of the magnetic field, a bias magnetic field is applied to the magnetic sensor. Examples known as methods for applying a bias magnetic field to a magnetic sensor include:

(a) a method in which a coil is disposed outside the magnetic sensor;
(b) a method in which a permanent magnet is disposed outside the magnetic sensor;
(c) a method in which a thin-film magnet is formed in a lower layer portion or an upper layer portion of the magnetic sensor, etc.

However, when a coil is used for applying a bias magnetic field to the magnetic sensor, it is necessary to apply an electric current to the coil. Therefore, there are problems such as (1) necessity of a dedicated power supply and a dedicated circuit, (2) difficulty in miniaturization, (3) large electric power consumption, etc.

When a permanent magnet is used, electric power is not consumed. However, the magnetic field changes in accordance with a distance from the magnet. It is therefore necessary to decide the attachment position of the magnet accurately. Thus, there is a problem that manufacturing becomes difficult.

On the other hand, when a thin-film magnet is used, the thin-film magnet can be manufactured in a similar fine processing process to that of the sensor element. It is therefore possible to decide the attachment position of the thin-film magnet comparatively accurately. However, there is a problem that the magnetic force of the thin-film magnet is too weak to provide a sufficient magnetic field easily.

In contrast, when a thin-film magnet is inserted at least just above or just below a GMR film (A) through an insulating film (A) in a thin-film magnetic sensor in which a high-sensitivity element and a low-sensitivity element have been connected in series, a bias magnetic field can be applied to the high-sensitivity element accurately without causing increase in electric power consumption or increase in element size. In addition, when dimensions of the thin-film magnet (that is, length, width and thickness of the thin-film magnet) are optimized, a relatively large bias magnetic field can be applied to the high-sensitivity element.

### EXAMPLES

### Examples 1 to 3

### 1. Test Method

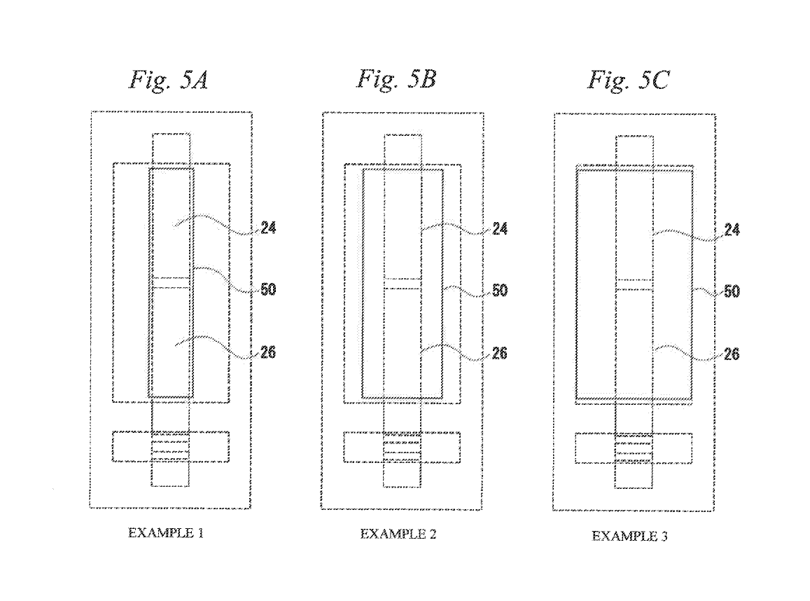

FIGS. 5A to 5C show plan views of thin-film magnetic sensors with thin-film magnets different in width. As shown in FIGS. 5A to 5C, thin-film magnetic sensors having the same yoke length of each thin-film yoke (A) 24, 26 (length of one thin-film yoke (A) in magnetic sensitive direction) and the same magnet length of the thin-film magnet 50 but different magnet widths (or different magnet width/yoke width ratios) were manufactured, and characteristics thereof were evaluated (Examples 1 to 3). Incidentally, gap length was set at 1 μm in each example. Table 1 shows the yoke length, the yoke width, the magnet length, the magnet width and the magnet width/yoke width ratio in each thin-film magnetic sensor.

TABLE 1

| | yoke | yoke | magnet | magnet | magnet width/yoke |
|---|---|---|---|---|---|
| | length | width | length | width | width ratio |
| Example 1 | 350 μm | 100 μm | 701 μm | 120 μm | 1.2 |
| Example 2 | 350 μm | 100 μm | 701 μm | 215 μm | 2.15 |
| Example 3 | 350 μm | 100 μm | 701 μm | 310 μm | 3.1 |

### 2. Results

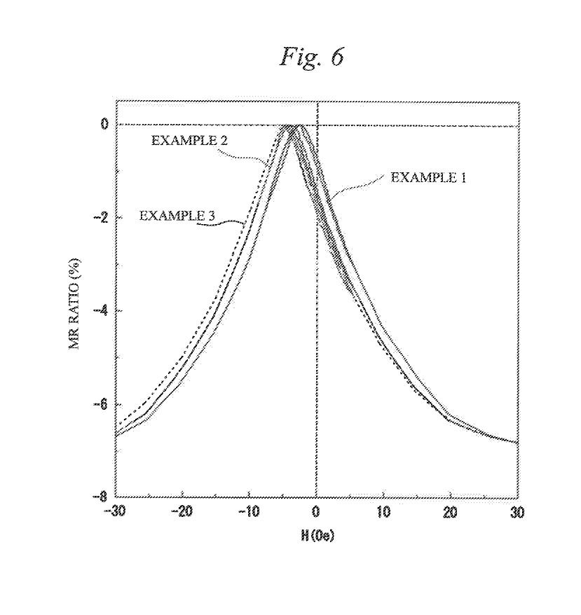

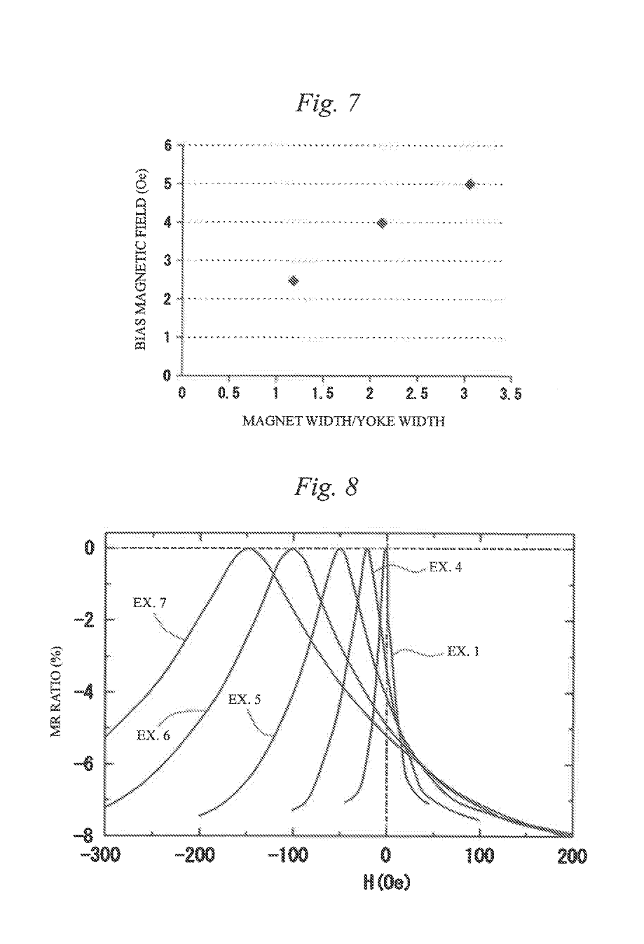

FIG. 6 shows MR curves of the thin-film magnetic sensors obtained in Examples 1 to 3. In addition, FIG. 7 shows magnet width/yoke width ratio dependency of a bias magnetic field applied to each of the thin-film magnetic sensors obtained in Examples 1 to 3. From FIG. 6 and FIG. 7, it is understood that a shift amount of each MR curve in a negative direction (that is, magnitude of the bias magnetic field) increases with increase in magnet width (or magnet width/yoke width ratio).

### Examples 4 to 7

### 1. Test Method

Thin-film magnetic sensors were manufactured in the same manner as in Example 1, except for differences in yoke length, magnet length and magnet width. The yoke length was set at 100 μm (Example 4), 50 μm (Example 5), 27 μm (Example 6), or 18 μm (Example 7). In addition, the magnet thickness was fixed in any example, the magnet length was set to be about twice as long as the yoke length, and the magnet width was set to be as long as the yoke width.

### 2. Results

FIG. 8 shows MR curves of the thin-film magnetic sensors different in yoke length, magnet length and magnet width. Incidentally, FIG. 8 also shows the result of Example 1. From FIG. 8, the followings can be understood.

(1) The shift amount of each MR curve in the negative direction (that is, the magnitude of the bias magnetic field) increased as the yoke length was shorter.
(2) As the yoke length of the high-sensitivity element 20 was shorter, the sensitivity to the external magnetic field was degraded. On the other hand, when the thin-film magnet 50 having a thickness substantially equal to the total length of the high-sensitivity element 20 was disposed just under the high-sensitivity element 20, the bias magnetic field applied to the high-sensitivity element 20 increased with reduction in yoke length. It is considered that this is because, as the length of the thin-film magnet 50 in the magnetic sensitive direction is shorter, leakage of flux is reduced so that a more intensive bias magnetic field can be applied to the high-sensitivity element 20.
(3) An element in which yoke length is made short to reduce sensitivity is useful due to a feature that the element has a wide operating magnetic field range. It is necessary to make a larger bias magnetic field act on such an element having a wide operating range. However, from the aforementioned results, it is understood that it is possible to make a sufficiently large bias magnetic field act on the element having a wide operating range.

### Examples 21 to 32

### 1. Test Method

Thin-film magnetic sensors were manufactured in the same manner as in Example 1, except for differences in magnet length, magnet width and magnet thickness. Characteristics of the thin-film magnetic sensors were evaluated. Incidentally, yoke length, yoke width and gap length were set at 350 μm, 100 μm and 1 μm, respectively.

### 2. Results

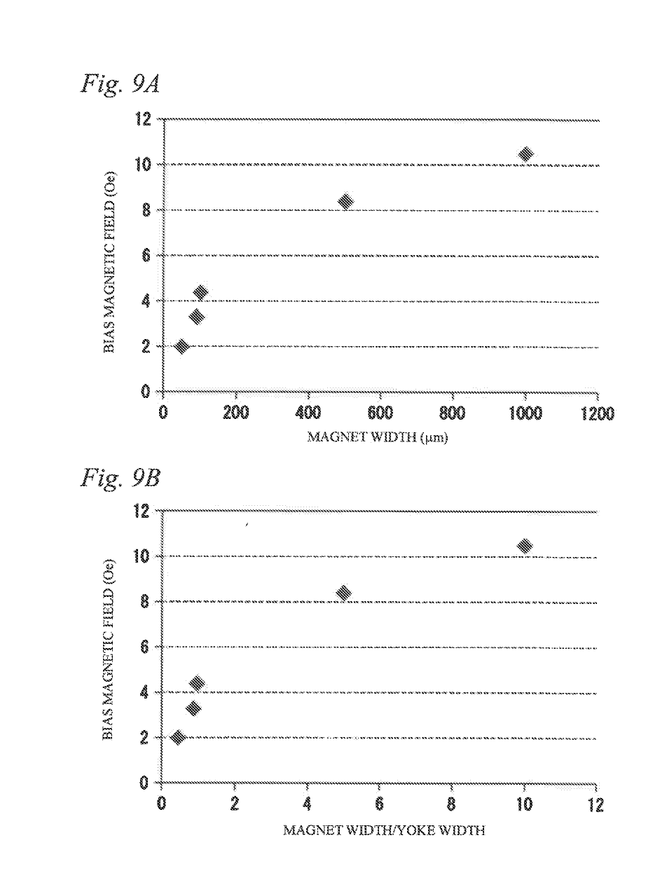

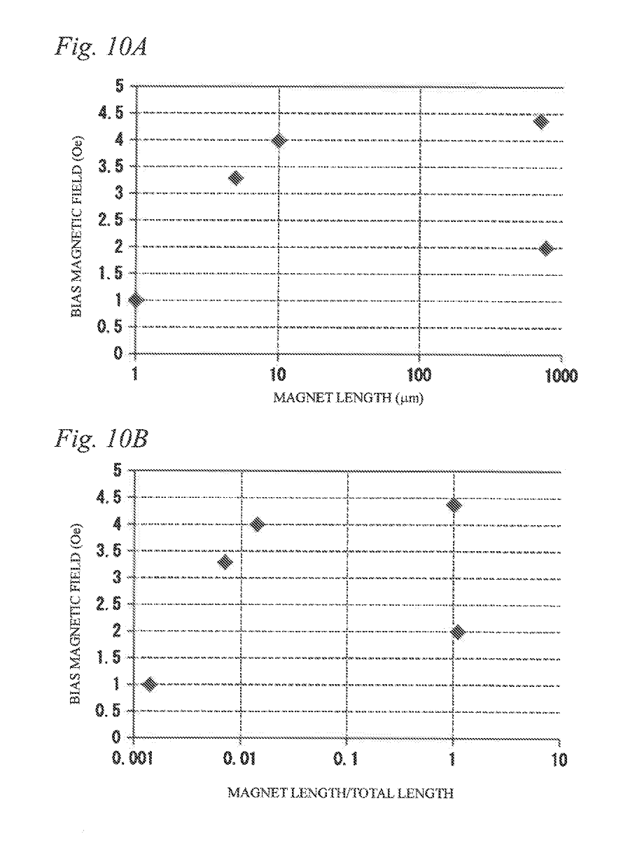

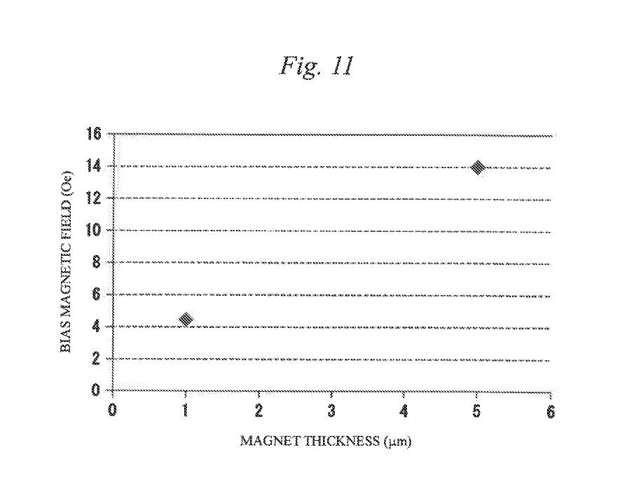

Table 2 shows the results. In addition, FIG. 9A shows a relation between a magnet width and a bias magnetic field. FIG. 9B shows a relation between a magnet width/yoke width ratio and a bias magnetic field. FIG. 10A shows a relation between a magnet length and a bias magnetic field. FIG. 10B shows a relation between a magnet length/total length ratio and a bias magnetic field. Further, FIG. 11 shows a relation between a magnetic thickness and a bias magnetic field. From Table 2 and FIGS. 9A, 9B, 10A, 10B and 11, the followings can be understood.

(1) The bias magnetic field increased with increase in magnet width/yoke width ratio. In addition, when the magnet width/yoke width ratio exceeded 10, a tendency to saturate the bias magnetic field could be recognized.
(2) Even when the magnet length was equal to the gap length, a bias magnetic field of about 1 [Oe] acted on the high-sensitivity element. In addition, the bias magnetic field increased with increase in magnet length/total length ratio. However, when the magnet length/total length ratio exceeded 1.0, the bias magnetic field dropped down suddenly. The bias magnetic field at the magnet length/total length ratio of 1.1 was reduced to ½ or lower of its peak value.
(3) The bias magnetic field increased with increase in the magnet thickness.

TABLE 2

| | magnet | magnet | magnet | magnet | bias | magnet | magnet |
|---|---|---|---|---|---|---|---|
| | length | width | thickness | volume | magnetic | length/yoke | width/yoke |
| No. | (μm) | (μm) | (μm) | (μm³) | field (Oe) | length ratio | width ratio |
| 21 | 701 | 100 | 1 | 70,100 | 4.4 | 1 | 1 |
| 22 | 701 | 50 | 1 | 35,050 | 2 | 1 | 0.5 |
| 23 | 701 | 90 | 1 | 63,090 | 3.3 | 1 | 0.9 |
| 24 | 701 | 500 | 1 | 350,500 | 8.4 | 1 | 5 |
| 25 | 701 | 1000 | 1 | 701,000 | 10.5 | 1 | 10 |
| 26 | 1 | 100 | 1 | 100 | 1 | 0.001426534 | 1 |
| 27 | 5 | 100 | 1 | 500 | 3.3 | 0.007132668 | 1 |
| 28 | 10 | 100 | 1 | 1,000 | 4 | 0.01426335 | 1 |
| 29 | 771 | 100 | 1 | 77,100 | 2 | 1.099857347 | 1 |
| 30 | 701 | 100 | 5 | 350,500 | 14 | 1 | 1 |
| 31 | 701 | 100 | 10 | 701,000 | ND | 1 | 1 |
| 32 | 701 | 100 | 100 | 7,010,000 | ND | 1 | 1 |

### Comparative Example 1

A thin-film magnetic sensor according to Patent Document 1 (that is, a thin-film magnetic sensor in which laminates each having a thin-film yoke and a thin-film magnet have been formed at both ends of a GMR film, and there is no insulating film between the thin-film yoke and the thin-film magnet) was manufactured, and characteristics thereof were evaluated (Comparative Example 1). Dimensions of each part were the same as those of Example 21, except that there is no thin-film magnet just below the GMR film (A) 22.

### 2. Results

In the thin-film magnetic sensor of Example 21, the bias magnetic field was 4.4 [Oe]. On the other hand, in the thin-film magnetic sensor of Comparative Example 1, the bias magnetic field was 2.0 [Oe]. That is, it is understood that the magnitude of the bias magnetic field can be increased to be two or more times when the thin-film magnet 50 is disposed just below the GMR film (A) 22 through the insulating film (A) 58a.

Although the present invention has been described in detail with reference to embodiments thereof, the present invention is not limited to the embodiments described above in any way, but various modifications can be made without departing from the gist of the invention.

The present application is based on Japanese Patent Application No. 2016-190765 filed on Sep. 29, 2016, and the contents are incorporated herein by reference.

The thin-film magnetic sensor according to the present invention can be used for detection of rotation information of automobile axles, rotary encoders, industrial gears and the like, detection of position-speed information of stroke positions of hydraulic cylinders/pneumatic cylinders, slides of machine-tools and the like, detection of current information of arc currents of industrial welding robots and the like, geomagnetic azimuth compasses and the like.

Further, the magnetoresistive element having the GMR film and the thin-film yokes disposed at both ends thereof is particularly suitable as the magnetic sensor. However, the use of the magnetoresistive element is not limited thereto, but it can be used as a magnetic memory, a magnetic head or the like.

### DESCRIPTION OF REFERENCE NUMERALS AND SIGNS

10a to 10d thin-film magnetic sensor
20 high-sensitivity element
22 GMR film (A)
24, 26 thin-film yoke (A)
30 low-sensitivity element
32 GMR film (B)
34, 36 thin-film yoke (B)
50 thin-film magnet
58a to 58c insulating film (A)

What is claimed is:

1. A thin-film magnetic sensor comprising:
a substrate;
a high-sensitivity element which is formed on the substrate and detects a change in an external magnetic field;
a low-sensitivity element which is formed on the substrate and connected in series with the high-sensitivity element, and which compensates fluctuation of a resistance value caused by a temperature change;
a thin-film magnet which applies a bias magnetic field to the high-sensitivity element; and
an insulating film (A) inserted between the high-sensitivity element and the thin-film magnet,
wherein the high-sensitivity element comprises: a GMR film (A) having a giant magnetoresistive effect; and a pair of thin-film yokes (A) made of a soft magnetic material and electrically connected to both ends of the GMR film (A),
the low-sensitivity element comprises: a GMR film (B) having a giant magnetoresistive effect; and a pair of thin-film yokes (B) made of a soft magnetic material and electrically connected to both ends of the GMR film (B), and
the thin-film magnet is disposed at least just below the GMR film (A) on the substrate side or just above the GMR film (A) on a side opposite to the substrate side.

2. The thin-film magnetic sensor according to claim 1, wherein the high-sensitivity element and the low-sensitivity element are disposed on one and the same plane.

3. The thin-film magnetic sensor according to claim 1, wherein a thickness (t_{M}) of the thin-film magnet is not smaller than 0.1 μm and not larger than 5 μm.

4. The thin-film magnetic sensor according to claim 2, wherein a thickness (t_{M}) of the thin-film magnet is not smaller than 0.1 μm and not larger than 5 μm.

5. The thin-film magnetic sensor according to claim 1, wherein a length (L_{M}) of the thin-film magnet in a magnetic sensitive direction is not smaller than gi and not larger than 1.1L, in which gₗ designates a length of the GMR film (A) in the magnetic sensitive direction, and L designates a total length of the high-sensitivity element in the magnetic sensitive direction.

6. The thin-film magnetic sensor according to claim 2, wherein a length (L_{M}) of the thin-film magnet in a magnetic sensitive direction is not smaller than gi and not larger than 1.1L, in which gₗ designates a length of the GMR film (A) in the magnetic sensitive direction, and L designates a total length of the high-sensitivity element in the magnetic sensitive direction.

7. The thin-film magnetic sensor according to claim 3, wherein a length (L_{M}) of the thin-film magnet in a magnetic sensitive direction is not smaller than gₗ and not larger than 1.1L, in which gₗ designates a length of the GMR film (A) in the magnetic sensitive direction, and L designates a total length of the high-sensitivity element in the magnetic sensitive direction.

8. The thin-film magnetic sensor according to claim 4, wherein a length (L_{M}) of the thin-film magnet in a magnetic sensitive direction is not smaller than gi and not larger than 1.1L, in which gₗ designates a length of the GMR film (A) in the magnetic sensitive direction, and L designates a total length of the high-sensitivity element in the magnetic sensitive direction.

9. The thin-film magnetic sensor according to claim 1, wherein a width (W_{M}) of the thin-film magnet is not smaller than 0.9W, in which W designates a width of each of the thin-film yokes (A).

10. The thin-film magnetic sensor according to claim 2, wherein a width (W_{M}) of the thin-film magnet is not smaller than 0.9W, in which W designates a width of each of the thin-film yokes (A).

11. The thin-film magnetic sensor according to claim 3, wherein a width (W_{M}) of the thin-film magnet is not smaller than 0.9W, in which W designates a width of each of the thin-film yokes (A).

12. The thin-film magnetic sensor according to claim 4, wherein a width (W_{M}) of the thin-film magnet is not smaller than 0.9W, in which W designates a width of each of the thin-film yokes (A).

13. The thin-film magnetic sensor according to claim 5, wherein a width (W_{M}) of the thin-film magnet is not smaller than 0.9W, in which W designates a width of each of the thin-film yokes (A).

14. The thin-film magnetic sensor according to claim 6, wherein a width (W_{M}) of the thin-film magnet is not smaller than 0.9W, in which W designates a width of each of the thin-film yokes (A).

15. The thin-film magnetic sensor according to claim 7, wherein a width (W_{M}) of the thin-film magnet is not smaller than 0.9W, in which W designates a width of each of the thin-film yokes (A).

16. The thin-film magnetic sensor according to claim 8, wherein a width (W_{M}) of the thin-film magnet is not smaller than 0.9W, in which W designates a width of each of the thin-film yokes (A).
